(19) United States
(12) Patent Application Publication
(10) Pub. No.: US 2013/0104979 A1
(43) Pub. Date: May 2, 2013

(54) SOLAR DEVICE USING OPTICAL FIBER

(71) Applicant: YUNG-LUN HUANG, Tu-Cheng (TW)

(72) Inventor: YUNG-LUN HUANG, Tu-Cheng (TW)

(73) Assignee: HON HAI PRECISION INDUSTRY CO., LTD., Tu-Cheng (TW)

(21) Appl. No.: 13/528,856

(22) Filed: Jun. 21, 2012

(30) Foreign Application Priority Data
Nov. 1, 2011 (TW) 100139678

(51) Int. Cl. H01L 31/0232

(52) U.S. Cl. 136/259

(57) ABSTRACT

A solar device includes a light condenser, a light guide member, a number of optical fibers and a converter end. The light condenser is configured for condensing incident light. The light guide member converts the condensed light into a plurality of focused light beams. The optical fibers receive the condensed light beams. The converter end includes a photoelectric converter configured for receiving and converting light from the optical fibers into electricity.

### BACKGROUND

1. Technical Field

The present disclosure relates to solar devices, and particularly to a solar device using one or more optical fibers.

2. Description of Related Art

Solar cell panels may be directly exposed to sunlight to receive and convert sunlight into electricity. However, an efficiency of the solar cell panel is influenced by an area size of the solar cell panel exposed to the sunlight, and such solar cell panels deteriorate and may even suffer damage over the long term because of dust and rain and pollution. In addition, such solar cell panels only provide for very local devices, as they are largely ineffective over long distances.

What is needed, therefore, is a solar device, which can overcome the above shortcomings.

### BRIEF DESCRIPTION OF THE DRAWINGS

Many aspects of the present solar device can be better understood with reference to the following drawings. The components in the drawings are not necessarily drawn to scale, the emphasis instead being placed upon clearly illustrating the principles of the present solar device. Moreover, in the drawings, like reference numerals designate corresponding parts throughout the several views.

FIG. 1 is a schematic view of a solar device in accordance with a first embodiment.

FIG. 2 is an isometric view of a light guide member shown in FIG. 1.

FIG. 3 is a schematic view of a solar device in accordance with a second embodiment.

### DETAILED DESCRIPTION

Embodiments of the present solar device will be described with reference to the drawings.

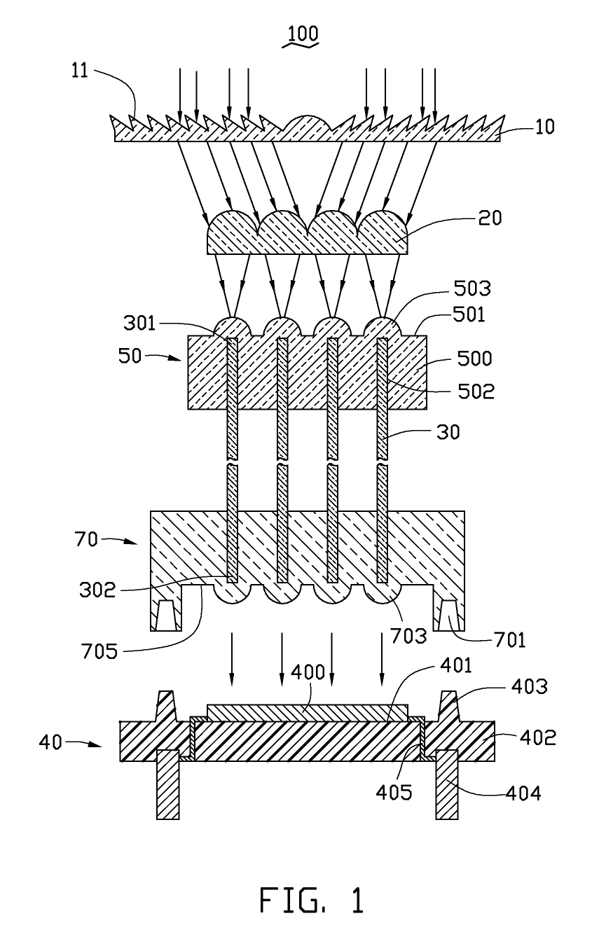

Referring to FIG. 1, a solar device 100 in accordance with a first embodiment is provided. The solar device 100 mainly includes a light condenser 10, a light guide member 20, a plurality of optical fibers 30 and a converter end 40. The converter end 40 includes at least one photoelectric converter 400 to convert light power to electrical power.

The light condenser 10 may be a light condensing lens, such as a convex lens or a Fresnel lens, and may be compound parabolic concentrator (CPC). In general, any light condenser 10 capable of condensing incident sunlight to a small area is acceptable. In the present embodiment, the light condenser 10 is a Fresnel lens. The Fresnel lens has a plurality of Fresnel-zones 11 arranged in concentric circles on the top surface.

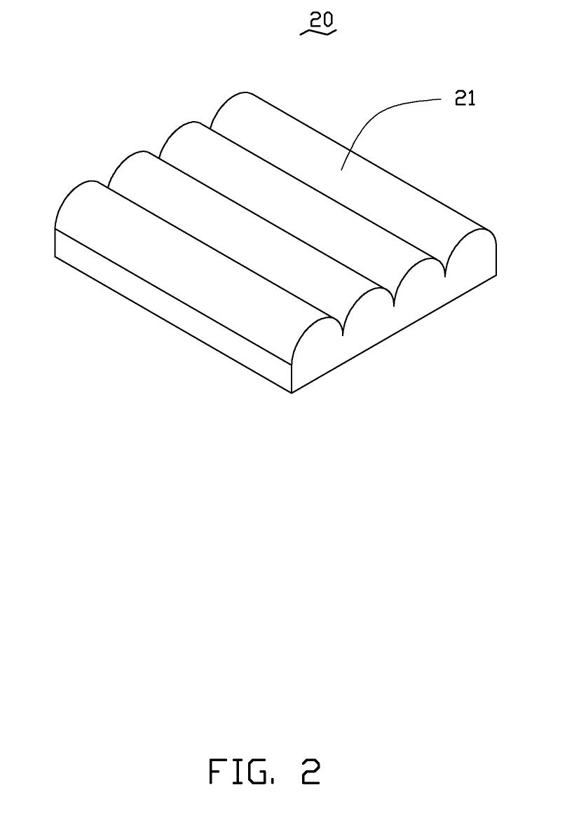

The light guide member 20 is located near to a focus of the light condenser 10, and configured for guiding the condensed light to the optical fibers 30. In the present embodiment, see also FIG. 2, the light guide member 20 is a lens block which has a plurality of converging lens portions 21. Each of the converging lens portions 21 has a focus point, such that the converging lens portions 21 can divide the condensed light from the light condenser 10 into light beams by further condensing the condensed light toward their respective focus points. The light beams then enter into the optical fibers 30.

In an alternative embodiment, when only one optical fiber 30 is used, the light guide member 20 may be a single converging lens. In other embodiments, when only one optical fiber 30 is used, the light guide member 20 may be avoided, and the optical fiber 30 may be arranged adjacent to the focus of the light condenser 10 to directly receive the condensed light.

In the present embodiment, input end 301 of all the optical fibers 30 is received in a first optical fiber connector 50, and the output end 302 of all the optical fibers 30 is received in a second optical fiber connector 70. In particular, the first optical fiber connector 50 includes a main body 500 having a top surface 501 facing toward the light guide member 20, and a plurality of first convex lenses 503 formed on the top surface. The first optical fiber connector 50 has inner blind holes 502 for receiving the optical fibers 30. The first convex lenses 503 are aligned with the optical fibers 30, and configured for further condensing the light beams from the light guide member 20 to the optical fibers 30.

The second optical fiber connector 70 has a structure similar to the first optical fiber connector 50. The second optical fiber connector 70 has a bottom surface 705 facing toward the converter end 40, and a plurality of second convex lenses 703 formed on the bottom surface 705. The second convex lenses 703 can gather the light from the optical fibers 30 to the photoelectric converter 400 on the converter end 40. In particular, the second optical fiber connector 70 has a plurality of hole portions 701 facing toward the converter end 40.

The converter end 40 includes a support 402 having a surface 401 facing toward the second optical fiber connector 70. The photoelectric converter 400 is located on the surface 401. The photoelectric converter 400 may use one or more semiconductors to convert sunlight into electricity. The support 402 has a plurality of protrusions 403 formed on the surface 401. The protrusions 403 can be inserted into the hole portions 701 of the second optical fiber connector 70.

The converter end 40 further includes a plurality of leads 404 electrically connected to the photoelectric converter 400 by electrical wires 405 buried in the support 402. The leads 404 can output electrical power.

A distance between the second optical fiber connector 70 and the first optical fiber connector 50 is according to need. In one application, the light condenser 10, the light guide member 20 and the first optical fiber connector 50 may be arranged on a roof, and the second optical fiber connector 70 and the converter end 40 may be arranged inside the building, then the first optical fiber connector 50 and the second optical fiber connector 70 have to be spaced apart according to the transmission distance. In another application, the whole solar device 100 can be arranged outdoors, then the first optical fiber connector 50 and the second optical fiber connector 70 can be integral or attached together.

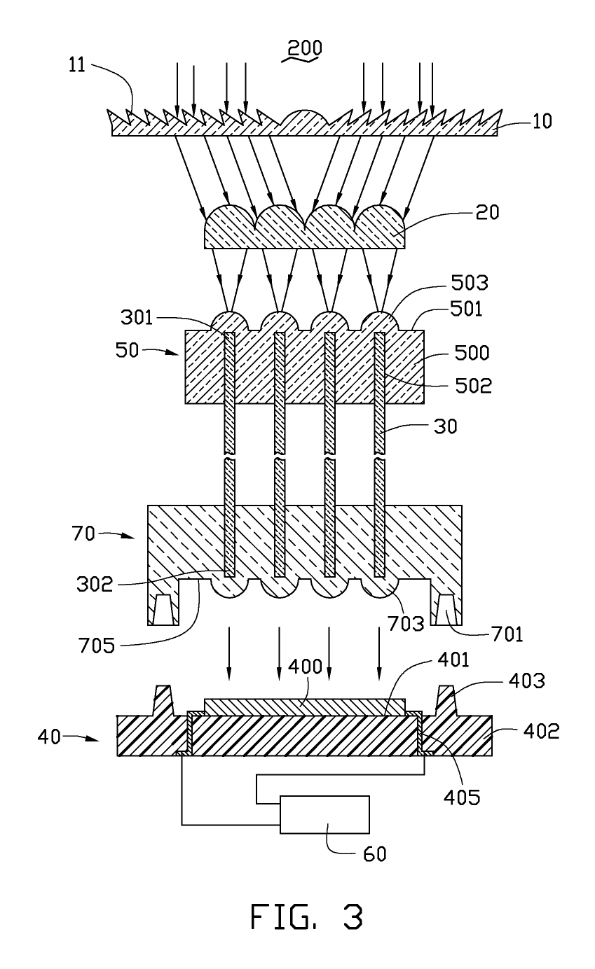

Referring to FIG. 3, a solar device 200 in accordance with a second embodiment is provided. The solar device 200 is essentially similar to the first solar device 100 illustrated above, however, the solar device 200 includes an inverter 60 electrically connected to the wire 405 to invert the output of direct current into alternating current.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A solar device, comprising:
a light condenser configured for condensing incident light;
at least one optical fiber having at least one input end receiving the condensed light and at least one output end; and
a converter end comprising a photoelectric converter configured for receiving light from the at least one output end and converting the received light from the at least one optical fiber into electricity.

2. The solar device of claim 1, wherein the light condenser is a Fresnel lens.

3. The solar device of claim 1, further comprising a light guide member configured for optically coupling the light condenser to the at least one optical fiber.

4. The solar device of claim 3, wherein the light guide member is a single converging lens, and the at least one optical fiber is only one optical fiber.

5. The solar device of claim 3, wherein the light guide member is a lens block having a plurality of converging lens portions each having a focus point, and the at least one optical fiber comprises a plurality of optical fibers optically coupled to the respective lens portions.

6. The solar device of claim 5, further comprising a first optical fiber connector connected with the input ends of the optical fibers, and a second optical fiber connector connected with the output ends of the optical fibers.

7. The solar device of claim 6, wherein the first optical fiber connector comprises a first surface facing toward the light condenser, and a plurality of first convex lenses formed on the first surface and optically aligned with the corresponding optical fibers.

8. The solar device of claim 6, wherein the second optical fiber connector comprises a second surface facing toward the converter end, and a plurality of second convex lenses formed on the second surface and optically aligned with the corresponding optical fibers.

9. The solar device of claim 8, wherein the second optical fiber connector further comprises a plurality of hole portions, the converter end further comprises a support having a surface supporting the photoelectric converter and a plurality of protrusions formed on the surface around the photoelectric converter, the protrusions insertable into the hole portions.

10. The solar device of claim 9, wherein the converter end further comprises a plurality of electrical wires buried in the support and a plurality of leads electrically connected to the wires.

11. The solar device of claim 9, wherein the converter end further comprises a plurality of electrical wires buried in the support and an inverter electrically connected to the electrical wires configured to invert direct current to alternate current.

12. A solar device, comprising:
a light condenser configured for condensing incident light;
a light guide member configured for converting the condensed light into a plurality of focused light beams;
a plurality of optical fibers configured for receiving the respective condensed light beams; and
a converter end comprising a photoelectric converter configured for receiving and converting light from the optical fibers into electricity.

13. The solar device of claim 12, wherein the light guide member is a lens block having a plurality of converging lens portions each having a focus point, and the optical fibers optically coupled to the respective lens portions.

14. The solar device of claim 12, further comprising a first optical fiber connector receiving an input end of each of the optical fibers, and a second optical fiber connector receiving an output end of each of the optical fibers.

15. The solar device of claim 14, wherein the first optical fiber connector comprises a first surface facing toward the light condenser, and a plurality of first convex lenses formed on the first surface and optically aligned with the corresponding optical fibers, the second optical fiber connector comprises a second surface facing toward the converter end, and a plurality of second convex lenses formed on the second surface and optically aligned with the corresponding optical fibers.
